(19) United States
(12) Patent Application Publication
(10) Pub. No.: US 2025/0203760 A1
(43) Pub. Date: Jun. 19, 2025

(54) DISPLAY APPARATUS AND TEST CIRCUIT BOARD

(71) Applicant: Samsung Display Co., LTD., Yongin-si (KR)

(72) Inventors: Jaesuk LEE, Yongin-si (KR); Hyunae KIM, Yongin-si (KR)

(21) Appl. No.: 18/816,109

(22) Filed: Aug. 27, 2024

(30) Foreign Application Priority Data
Dec. 15, 2023 (KR) 10-2023-0182947

(51) Int. Cl. H05K 1/02; H10K 59/90

(52) U.S. Cl. CPC H05K 1/0268; H10K 59/90

(57) ABSTRACT

A display apparatus includes a substrate including a display area where a plurality of display elements are disposed, and a display circuit board disposed outside the display area. The display circuit board includes a first pad and a second pad, which are disposed on the display circuit board and connected to the substrate, and an insulating layer disposed between the first pad and the second pad, and the first pad overlaps the second pad and a thickness of at least a portion of the second pad is different from a thickness of the first pad.

This application claims priority to Korean Patent Application No. 10-2023-0182947, filed on Dec. 15, 2023, and all the benefits accruing therefrom under 35 U.S.C. § 119, the content of which in its entirety is herein incorporated by reference.

### BACKGROUND

### 1. Field

Embodiments relate to a display apparatus and a test circuit board. More particularly, embodiments relate to a display apparatus including a light-emitting diode and a test circuit board for testing a printed circuit board in a display apparatus.

### 2. Description of the Related Art

A display apparatus may provide visual information such as an image or a video to a user. The display apparatus may include a substrate divided into a display area and a peripheral area. In the display area, a scan line and a data line are insulated from each other and a plurality of pixels may be provided. Also, in the display area, a thin-film transistor and a pixel electrode electrically connected to the thin-film transistor may be provided for each pixel. In addition, an opposing electrode may be commonly provided in the display area for the pixels. Various wires transmitting electric signals to the display area, a scan driver, a data driver, a controller, and a pad unit may be provided in the peripheral area.

A display apparatus may include a printed circuit board (“PCB”) which transmits an electric signal. Various types of electronic components may be disposed (e.g., mounted) on the PCB. Also, the PCB may include pads that contact and are electrically connected to other components.

### SUMMARY

A printed circuit board (“PCB”) may be connected to a test circuit board and an electric signal may be applied to the PCB so as to test a performance of the PCB and detect an error. The pad of the PCB and a pad of the test circuit board need to be aligned to correctly contact with each other. A separation distance between the pads, which allow a test to be normally performed despite a partial error in the alignment of the pad of the PCB and the pad of the test circuit board, is also referred to as a contact margin. When the contact margin is not sufficiently secured, even small errors in alignment may result in false detections such as a failure to inspect or defective inspection during a test process.

Additional features will be set forth in part in the description which follows and, in part, will be apparent from the description, or may be learned by practice of the presented embodiments of the disclosure.

In an embodiment of the disclosure, a display apparatus includes a substrate including a display area where a plurality of display elements is disposed, and a display circuit board disposed outside the display area, wherein the display circuit board includes a first pad and a second pad, which are disposed on the display circuit board to be connected to the substrate, and an insulating layer disposed between the first pad and the second pad, and the first pad overlaps the second pad and a thickness of at least a portion of the second pad is different from a thickness of the first pad.

In an embodiment, the second pad may include a first portion overlapping the first pad and a second portion non-overlapping the first pad, wherein a thickness of the first portion may be less than a thickness of the second portion.

In an embodiment, the insulating layer may include a first portion disposed between the first pad and the first portion of the second pad and a second portion disposed between the first pad and the second portion of the second pad.

In an embodiment, a thickness of the first portion of the insulating layer may be equal to or greater than at least one of the thickness of the first pad and the thickness of the first portion of the second pad.

In an embodiment, top surfaces of the first pad, the second pad, and the insulating layer may be disposed in a same plane.

In an embodiment, the insulating layer may contact at least one of the first pad and the second pad on two surfaces of the at least one of the first pad and the second pad, and the two surfaces extend along different directions from each other.

In an embodiment, the insulating layer may contact a side surface and a bottom surface of the first pad, which face the second pad and may contact a side surface and a top surface of the second pad, which face the first pad.

In an embodiment, the two surfaces extending in the different directions from each other may share a same edge.

In an embodiment, the display apparatus may further include a plurality of first pads spaced apart from each other in a first direction and a plurality of second pads spaced apart from each other in the first direction, and in a plane, a distance between adjacent first pads of the plurality of first pads in the first direction may be equal to or greater than a width of one of the plurality of first pads in the first direction.

In an embodiment, in a plane, the first pad and the second pad may be spaced apart from each other in a second direction with the insulating layer therebetween, and a length of the insulating layer in the second direction may be equal to or greater than a length of at least one of the first pad and the second pad in the second direction.

In an embodiment of the disclosure, a test circuit board for testing a display circuit board disposed outside a display apparatus, includes a first test pad, a second test pad spaced apart from the first test pad, and an insulating layer disposed between the first test pad and the second test pad, wherein the first test pad overlaps the second test pad and a thickness of at least a portion of the second test pad is different from a thickness of the first test pad.

In an embodiment, the second test pad may include a first portion overlapping the first test pad and a second portion non-overlapping the first test pad, wherein a thickness of the first portion may be less than a thickness of the second portion.

In an embodiment, the insulating layer may include a first portion disposed between the first test pad and the first portion of the second test pad and a second portion disposed between the first test pad and the second portion of the second test pad.

In an embodiment, a thickness of the first portion of the insulating layer may be equal to or greater than at least one of the thickness of the first test pad and the thickness of the first portion of the second test pad.

In an embodiment, top surfaces of the first test pad, second test pad, and insulating layer may be disposed in a same plane.

In an embodiment, the insulating layer may contact at least one of the first test pad and the second test pad on two surfaces of the at least one of the first test pad and the second test pad, and the two surfaces extend along different directions from each other.

In an embodiment, the insulating layer may contact a side surface and a bottom surface of the first test pad, which face the second test pad and may contact a side surface and a top surface of the second test pad, which face the first test pad.

In an embodiment, the two surfaces extending in the different directions from each other may share a same edge.

In an embodiment, the test circuit board may further include a plurality of first test pads spaced apart from each other in a first direction and a plurality of second test pads spaced apart from each other in the first direction, and in a plane, a distance between adjacent first test pads of the plurality of first test pads in the first direction may be equal to or greater than a length of one of the plurality of first test pads in the first direction.

In an embodiment, in a plane, the first test pad and the second test pad may be spaced apart from each other in a second direction with the insulating layer therebetween, and a length of the insulating layer in the second direction may be equal to or greater than a length of at least one of the first test pad and the second test pad in the second direction.

### BRIEF DESCRIPTION OF THE DRAWINGS

The above and other features and advantages of illustrative embodiments of the disclosure will be more apparent from the following description taken in conjunction with the accompanying drawings, in which:

FIG. 1A is a plan view of an embodiment of a display apparatus;

FIG. 1B is a side view of an embodiment of the display apparatus including components shown in FIG. 1A;

FIG. 2A is a plan view of an embodiment of a display apparatus;

FIG. 2B is a side view of the display apparatus including components shown in FIG. 2A;

FIG. 3 is a cross-sectional view of an embodiment of a portion of a display area of a display apparatus;

FIG. 4A is a plan view of a portion of an embodiment of a display circuit board;

FIG. 4B is a plan view of a portion of an embodiment of a display circuit board;

FIG. 5 is an enlarged plan view of a portion of an embodiment of a display circuit board;

FIG. 6A is a cross-sectional view of an embodiment of a pad unit;

FIG. 6B is a cross-sectional view of an embodiment of a pad unit;

FIG. 7 is a perspective view of a portion of an embodiment of a circuit board test apparatus;

FIGS. 8A and 8B are perspective views illustrating an embodiment of stages of a method for testing a display circuit board;

FIG. 9 is a plan view of an embodiment of an alignment state of a pad unit and a test pad unit;

FIG. 10 is a plan view of an embodiment of an alignment state of a pad unit and a test pad unit; and

FIG. 11 is a plan view of an embodiment of an alignment state of a pad unit and a test pad unit.

### DETAILED DESCRIPTION

The disclosure may have various modifications and various embodiments, and illustrative embodiments are illustrated in the drawings and are described in detail in the detailed description. Effects and features of the disclosure and methods of achieving the same will become apparent with reference to embodiments described in detail with reference to the drawings. However, the disclosure is not limited to the embodiments described below, and may be implemented in various forms.

Hereinafter, embodiments will be described in detail with reference to the accompanying drawings, and in the following description with reference to the drawings, like reference numerals refer to like elements and redundant descriptions thereof will be omitted.

In the following embodiments, the terms “first” and “second” are not used in a limited sense and are used to distinguish one component from another component.

In the following embodiments, an expression used in the singular encompasses the expression of the plural, unless it has a clearly different meaning in the context.

In the following embodiments, it will be further understood that the terms “comprise” and/or “comprising” used herein specify the presence of stated features or components, but do not preclude the presence or addition of one or more other features or components.

It will be understood that when a layer, region, or element is referred to as being “formed on” another layer, area, or element, it may be directly or indirectly formed on the other layer, region, or element. That is, for example, intervening layers, regions, or elements may be present.

In the drawings, for convenience of description, sizes of components may be exaggerated or reduced. In other words, because sizes and thicknesses of components in the drawings are arbitrarily illustrated for convenience of explanation, the disclosure is not necessarily limited thereto.

When an illustrative embodiment may be implemented differently, a specific process order may be performed differently from the described order. For example, two consecutively described processes may be performed substantially at the same time or performed in an order opposite to the described order.

In the specification, “A and/or B” denotes only A, only B, or both A and B. Also, “at least one of A and B” denotes only A, only B, or both A and B.

When a layer, region, component, or the like is connected to another layer, region, component, or the like, the layer, the region, the component, or the like may be directly connected thereto and/or may be indirectly connected thereto with an intervening layer, region, component, or the like therebetween.

An x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

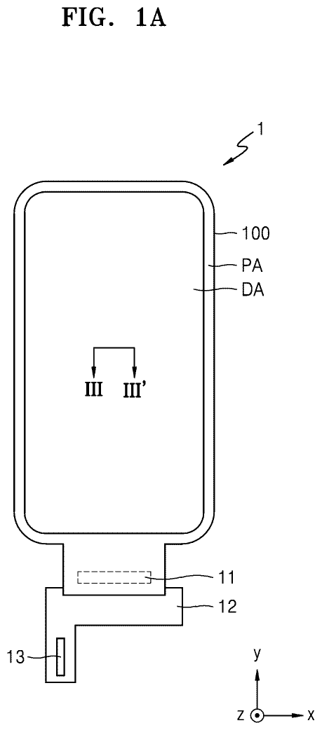

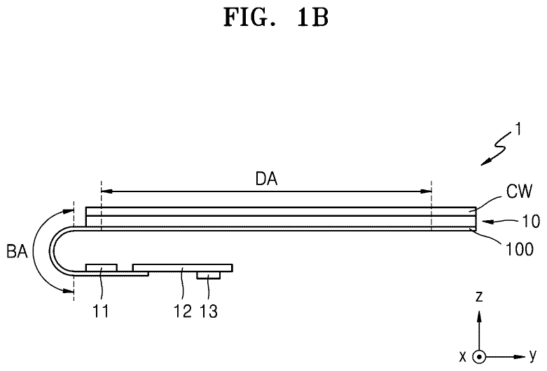

FIG. 1A is a plan view of an embodiment of a display apparatus 1. FIG. 1B is a side view of the display apparatus 1 including components shown in FIG. 1A.

In FIG. 1B, a substrate 100 is a flexible substrate, and thus, a display panel 10 is bent in a bending area BA. FIG. 1A illustrates the display panel 10 in an unbent state for convenience.

Referring to FIGS. 1A and 1B, the display apparatus 1 in an embodiment is an apparatus which displays a moving image or a still image, and may be used as a display screen of not only a portable electronic device, such as a mobile phone, a smartphone, a tablet personal computer (“PC”), a mobile communication terminal, an electronic notebook, an electronic book, a portable multimedia player (“PMP”), a navigation device, and an ultra mobile PC (“UMPC”), but also various products such as a television, a laptop computer, a monitor, a billboard, and an Internet of things (“IoT”). Also, the display apparatus 1 may be used for a wearable device, such as a smart watch, a watch phone, a glasses-type display, or a head mounted display (“HMD”). In addition, the display apparatus 1 may be used as a dashboard of a vehicle, a center information display (“CID”) disposed on a center fascia or dashboard of a vehicle, a room mirror display replacing a side mirror of a vehicle, or a display disposed on a rear surface of a front seat, as entertainment for a back seat of a vehicle.

For convenience of description, the display apparatus 1 is used as a smartphone in FIGS. 1A and 1B. The display apparatus 1 includes a cover window CW, the display panel 10, a display driver 11, a display circuit board 12, and a sensor driver 13. Obviously, the display apparatus 1 may further include a bracket, a main circuit board, a battery, and a lower cover, which are not illustrated.

Hereinafter, the term “upper” denote a direction in which the cover window CW is disposed with respect to the display panel 10, i.e., a +z direction, and the term “lower” denotes a direction opposite thereto with respect to the display panel 10, i.e., a −z direction. In the drawings, x, y, and z directions indicated by arrows may be +x, +y and +z directions, and opposite directions may be −x, −y and −z directions, respectively.

When viewed in a direction perpendicular to a surface of the display apparatus 1, the display apparatus 1 may have an approximately quadrangular shape, e.g., rectangular shape as shown in FIG. 1A. In an embodiment, as shown in FIG. 1A, the display apparatus 1 may have a quadrangular shape, e.g., rectangular plane shape in overall, which has short sides extending in a +x direction and long sides extending in a ty direction. A corner where the short side in the +x direction and the long side in the ty direction meet may have a right-angle shape or a round shape having a predetermined curvature. Obviously, a plane shape of the display apparatus 1 is not limited to a rectangle, and may be a polygon, a circle, or an oval.

As shown in FIG. 1B, the cover window CW may be disposed on the display panel 10 to cover a top surface of the display panel 10. The cover window CW may perform a function of protecting the top surface of the display panel 10.

The display panel 10 may be disposed below the cover window CW. The display panel 10 may overlap a transmitting portion of the cover window CW. The display panel 10 may include the substrate 100 and display elements arranged on the substrate 100.

The display panel 10 displays (outputs) information processed by the display apparatus 1. In an embodiment, the display panel 10 may display execution screen information of an application driven by the display apparatus 1 or user interface (“UI”) or graphical user interface (“GUI”) information according to the execution screen information, for example. The display panel 10 may include a display layer displaying an image and a touch layer detecting a touch input of a user. Accordingly, the display panel 10 may function as one of input devices which provide an input interface between the display apparatus 1 and the user and at the same time, function as one of output units which provide an output interface between the display apparatus 1 and the user.

The substrate 100 included in the display panel 10 may include an insulating material, such as glass, quartz, or polymer resin. The substrate 100 may be a rigid substrate or a flexible substrate capable of being bent, folded, or rolled. In FIG. 1B, the substrate 100 is a flexible substrate, and thus, the display panel 10 is bent in the bending area BA.

The substrate 100 includes a display area DA and a peripheral area PA outside the display area DA, and display elements may be arranged in the display area DA of the substrate 100. The peripheral area PA of the substrate 100 may be an area where an image is not displayed. The peripheral area PA may surround the display area DA. The peripheral area PA may be an area from an edge of the display area DA to an edge of the display panel 10. Not only pixels, but also scan wires, data wires, and power supply wires, which are connected to the pixels, may be arranged in the display area DA. A scan driver which applies scan signals to the scan wires and fanout wires connecting the data wires to the display driver 11 may be located in the peripheral area PA.

The display elements may include, e.g., a light-emitting element. In an embodiment, the display panel 10 may be an organic light-emitting display panel using an organic light-emitting diode including an organic emission layer, a micro light-emitting diode (“LED”) display panel using a micro-LED, a quantum dot light-emitting display panel using a quantum dot LED including a quantum dot emission layer, or an inorganic light-emitting display panel using an inorganic LED including an inorganic semiconductor, for example.

As shown in FIG. 1B, the display panel 10 may include the bending area BA at one side in the −y direction and the display panel 10 may be bent in the bending area BA. In other words, FIG. 1A illustrates the display panel 10 in the unbent state for convenience. When the display panel 10 is bent as such, the display driver 11, the display circuit board 12, and the sensor driver 13 are disposed below the display panel 10 in the −z direction.

The display driver 11 may receive control signals and power voltages, and generate and output signals and voltages for driving the display panel 10. The display driver 11 may include an integrated circuit (“IC”).

The display circuit board 12 may be electrically connected to the display panel 10. Also, the display circuit board 12 may be electrically connected to a main circuit board that is not illustrated. The main circuit board may include a main processor including an IC, a camera device, a wireless communicator, an input unit, an output unit, an interface unit, a memory, and/or a power supplier, for example. To be connected to the display panel 10 and/or the main circuit board, the display circuit board 12 may overlap the substrate 100 as shown in FIGS. 1A and 1B. Here, the substrate 100 and the display circuit board 12 may each include a plurality of pads protruding towards each other. The pads of the substrate 100 and the pads of the display circuit board 12 contact each other to electrically connect the display circuit board 12 to the substrate 100, and in addition, to the display panel 10 and the main circuit board.

The display circuit board 12 may be a flexible printed circuit board (“FPCB”) that is bendable or a rigid printed circuit board (“PCB”) that is rigid and does not bend easily, and in some cases, may be a complex PCB including both a rigid PCB and an FPCB.

The sensor driver 13 may be disposed on the display circuit board 12. The sensor driver 13 may include an IC. The sensor driver 13 may be attached on the display circuit board 12. The sensor driver 13 may be electrically connected to touch electrodes of the display panel 10 through the display circuit board 12.

In addition, the pixels of the display panel 10, the scan driver, and a power supplier which supplies driving voltages for driving the display driver 11 may be additionally disposed on the display circuit board 12.

Although not illustrated in FIG. 1B, a panel lower cover may be disposed below the display panel 10. The panel lower cover may include at least one of a light absorption member for absorbing light incident from the outside, a buffer member for absorbing an external impact, and a heat dissipation member for efficiently emitting heat of the display panel 10.

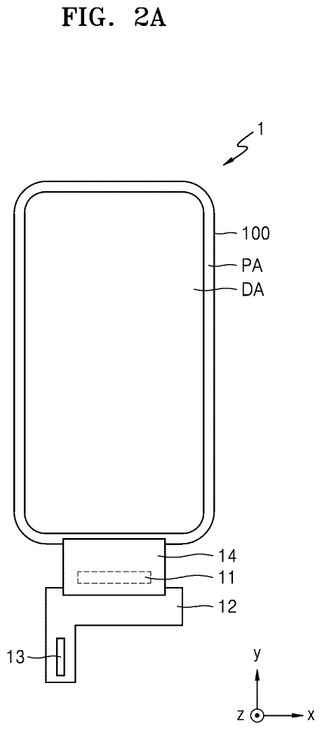

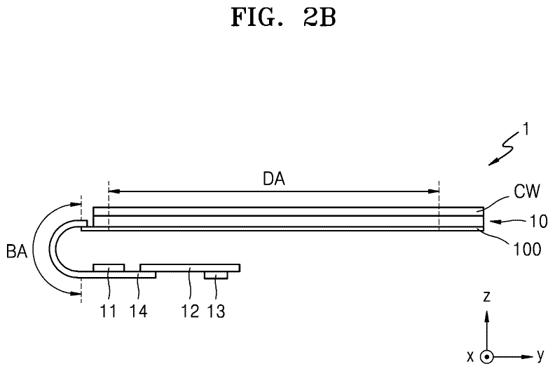

FIG. 2A is a plan view of an embodiment of the display apparatus 1. FIG. 2B is a side view of the display apparatus 1 including components shown in FIG. 2A.

In FIG. 2B, the substrate 100 is a flexible substrate, and thus, the display panel 10 is bent in the bending area BA. FIG. 2A illustrates the display panel 10 in the unbent state for convenience.

Referring to FIGS. 2A and 2B, the substrate 100 may not be bent. Instead, a circuit film 14 that is electrically connected to the substrate 100 while overlapping the same may be bent. Although not illustrated in FIG. 2B, pads that protrude from the substrate 100 and the circuit film 14 to contact each other may be disposed between the substrate 100 and the circuit film 14.

The circuit film 14 may be bent in the bending area BA such that a portion thereof is disposed below the substrate 100. The circuit film 14 may include a flexible material. In an embodiment, the circuit film 14 may include polyimide (“PI”). The circuit film 14 may include a circuit formed on a surface thereof. The display driver 11 may be disposed on the circuit film 14. The display driver 11 may be electrically connected to the display panel 10 through the circuit formed on the circuit film 14.

The display circuit board 12 may be disposed below the substrate 100 and may overlap the circuit film 14. Here, the circuit film 14 and the display circuit board 12 may each include a plurality of pads protruding towards each other. The pads of the circuit film 14 and the pads of the display circuit board 12 contact each other to electrically connect the display circuit board 12 to the circuit film 14, and in addition, to the substrate 100, the display panel 10, and the main circuit board.

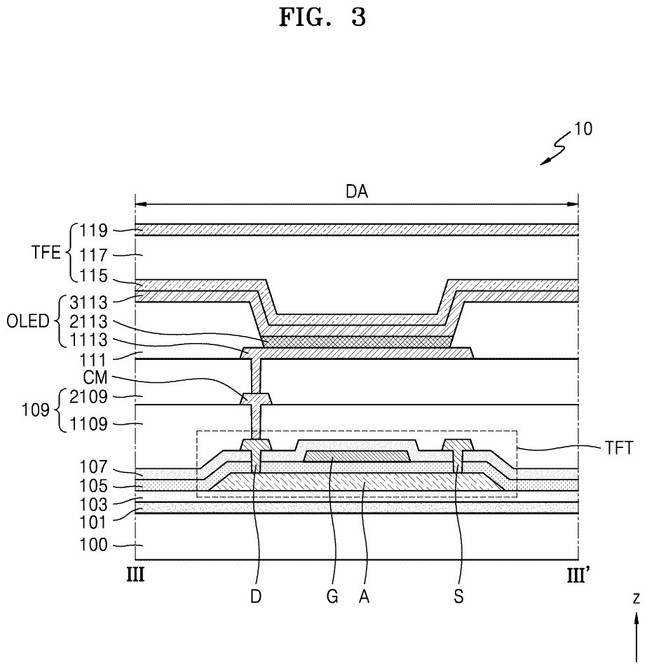

FIG. 3 is a cross-sectional view of an embodiment of a portion of the display area DA of the display apparatus 1. FIG. 3 may be a cross-sectional view of the display apparatus 1 taken along line III-III′ of FIG. 1A.

Referring to FIG. 3, an organic light-emitting diode OLED may be disposed on the substrate 100, as a display element. The organic light-emitting diode OLED may be electrically connected to a thin-film transistor TFT.

A barrier layer 101 and a buffer layer 103 may be arranged on the substrate 100. The barrier layer 101 and the buffer layer 103 may planarize the top surface of the substrate 100 while protecting the same. The barrier layer 101 and the buffer layer 103 may include an inorganic insulating material, such as silicon oxide (SiOₓ), silicon nitride (SiNₓ) and/or silicon oxynitride (SiON), and may have a single layer or multi-layer structure of the above-described materials.

The thin-film transistor TFT may be disposed on the buffer layer 103. The thin-film transistor TFT may include an active layer A, a gate electrode G, a source electrode S, and a drain electrode D. The thin-film transistor TFT may be connected to the organic light-emitting diode OLED to drive the organic light-emitting diode OLED.

The active layer A may be disposed on the buffer layer 103 and may include a drain region overlapping the drain electrode D, a source region overlapping the source electrode S, and a channel region provided between the drain region and the source region. The active layer A may include a semiconductor pattern, and the drain region and the source region of the active layer A may be impurity-doped regions.

A gate insulating layer 105 may be disposed on the active layer A. The gate insulating layer 105 may include an inorganic material including an oxide or a nitride. In an embodiment, the gate insulating layer 105 may include SiOₓ, SiNₓ, SiON, aluminum oxide (Al₂O₃), titanium oxide (TiO₂), tantalum oxide (Ta₂O₅), hafnium oxide (HfO₂), and/or zinc oxide (ZnO₂), and may have a single layer or multi-layer structure of the above-described materials, for example.

The gate electrode G may be disposed on the gate insulating layer 105. The gate electrode G may at least partially overlap the active layer A. In an embodiment, the gate electrode G may overlap the channel region of the active layer A. The gate electrode G may include aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single layer or multi-layer structure including the above-described materials, for example.

An inter-insulating layer 107 may be disposed to cover the gate electrode G. The inter-insulating layer 107 may include an inorganic material including an oxide or a nitride. In an embodiment, the inter-insulating layer 107 may include SiOₓ, SiNₓ, SiON, Al₂O₃, TiO₂, Ta₂O₅, HfO₂, and/or ZnO₂, and may have a single layer or multi-layer structure of the above-described materials, for example.

Contact holes overlapping the source region and drain region of the active layer A may be defined in the gate insulating layer 105 and the inter-insulating layer 107. The source electrode S and the drain electrode D may be disposed on the inter-insulating layer 107. The source electrode S may be disposed while overlapping the source region of the active layer A, and the drain electrode D may be disposed while overlapping the drain region of the active layer A. The source electrode S and the drain electrode D may be connected to the active layer A through the contact holes respectively formed in the gate insulating layer 105 and the inter-insulating layer 107.

An organic insulating layer 109 may be disposed on the inter-insulating layer 107. In an embodiment, first and second organic insulating layers 1109 and 2109 may be sequentially disposed on the inter-insulating layer 107, for example. The first and second organic insulating layers 1109 and 2109 may each define an opening overlapping the drain electrode D. A connecting metal CM may be disposed on the first organic insulating layer 1109. The connecting metal CM may be disposed on the first organic insulating layer 1109 and connected to the drain electrode D through the opening of the first organic insulating layer 1109. The second organic insulating layer 2109 may be disposed on the first organic insulating layer 1109 and include the opening overlapping the connecting metal CM.

The connecting metal CM may include AL, Cu, and/or Ti, and include a single layer or multi-layer including the above-described materials.

The first and second organic insulating layers 1109 and 2109 may include a general-purpose polymer, such as benzocyclobutene, polyimide, hexamethyldisiloxane, polymethylmethacrylate, or polystyrene, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer, and may have a single layer or multi-layer structure of the above-described materials.

In FIG. 3, two organic insulating layers and one connecting metal are illustrated, but the disclosure is not limited thereto. In an embodiment, a display panel may include three or more organic insulating layers and a plurality of connecting metals.

The organic light-emitting diode OLED may be disposed on the organic insulating layer 109 and include a sub-pixel electrode 1113, an intermediate layer 2113, and an opposing electrode 3113.

The sub-pixel electrode 1113 may be disposed on the second organic insulating layer 2109. The sub-pixel electrode 1113 may be connected to the connecting metal CM through the opening of the second organic insulating layer 2109. Accordingly, the sub-pixel electrode 1113 may be electrically connected to the thin-film transistor TFT through the connecting metal CM and the drain electrode D, and may receive a voltage.

The sub-pixel electrode 1113 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). The sub-pixel electrode 1113 may include a reflective layer including Ag, Mg, Al, Pt, Pd, Au, Ni, Nd, Ir, Cr, or any combinations thereof. Obviously, a configuration and material of the sub-pixel electrode 1113 are not limited thereto and may vary.

A bank layer 111 may be disposed on the organic insulating layer 109, e.g., the second organic insulating layer 2109. The bank layer 111 may cover an edge (or an edge region) of the sub-pixel electrode 1113. In other words, an opening which exposes a portion of a center of the sub-pixel electrode 1113 may be defined in the bank layer 111. A size and shape of an emission region of the organic light-emitting diode OLED may be determined by the opening of the bank layer 111.

The intermediate layer 2113 may be disposed on the sub-pixel electrode 1113. The intermediate layer 2113 may include an organic emission layer including a low-molecular weight or high-molecular weight material. In an embodiment, the intermediate layer 2113 may include an electron transport layer (“ETL”) and/or an electron injection layer (“EIL”). In an embodiment, the intermediate layer 2113 may include a hole transport layer (“HTL”) and/or a hole injection layer (“HIL”). In an embodiment, the intermediate layer 2113 may include a plurality of ETL and/or EIL and/or HTL and/or HIL.

The opposing electrode 3113 may be disposed on the intermediate layer 2113. The opposing electrode 3113 may be disposed to cover an entirety of the intermediate layer 2113. The opposing electrode 3113 may include a conductive material with a relatively low work function. In an embodiment, the opposing electrode 3113 may include a (semi-) transparent layer including Ag, Mg, Al, Pt, Pd, Au, Ni, Nd, Ir, Cr, lithium (Li), calcium (Ca), or any alloys thereof, for example. In an alternative embodiment, the opposing electrode 3113 may further include a layer including ITO, IZO, ZnO, or In₂O₃, on the (semi-) transparent layer including the above material.

In an embodiment, a capping layer may be disposed on the opposing electrode 3113 to cover an entirety of the opposing electrode 3113.

A thin-film encapsulation layer TFE may be disposed on the opposing electrode 3113. The thin-film encapsulation layer TFE may include at least one inorganic layer and at least one organic layer. In an embodiment, the thin-film encapsulation layer TFE may include first and second inorganic encapsulation layers 115 and 119, and an organic encapsulation layer 117 therebetween. The first and second inorganic encapsulation layers 115 and 119 may include one or more inorganic insulating materials, such as SiO₂, SiNₓ, SiON, Al₂O₃, TiO₂, Ta₂O₅, HfO₂, and/or ZnO₂. The organic encapsulation layer 117 may include a polymer-based material. In embodiments, the polymer-based material may include a silicon-based resin, an acryl-based resin, an epoxy-based resin, polyimide, and polyethylene.

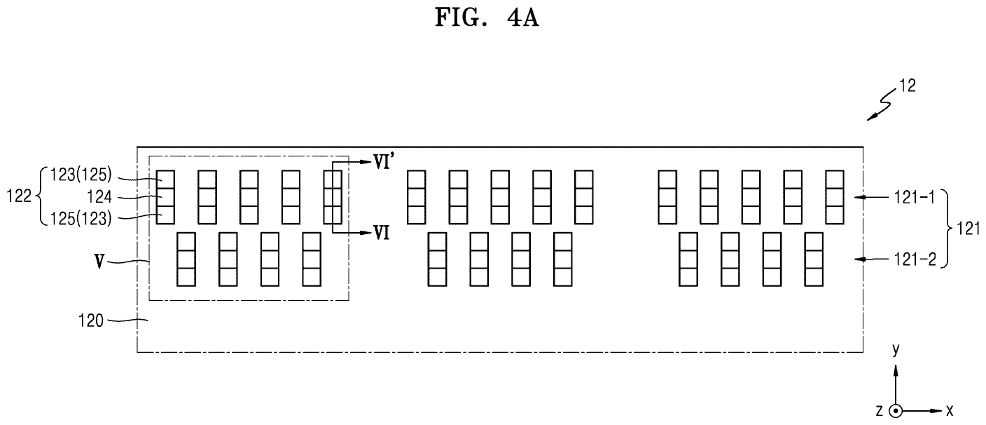

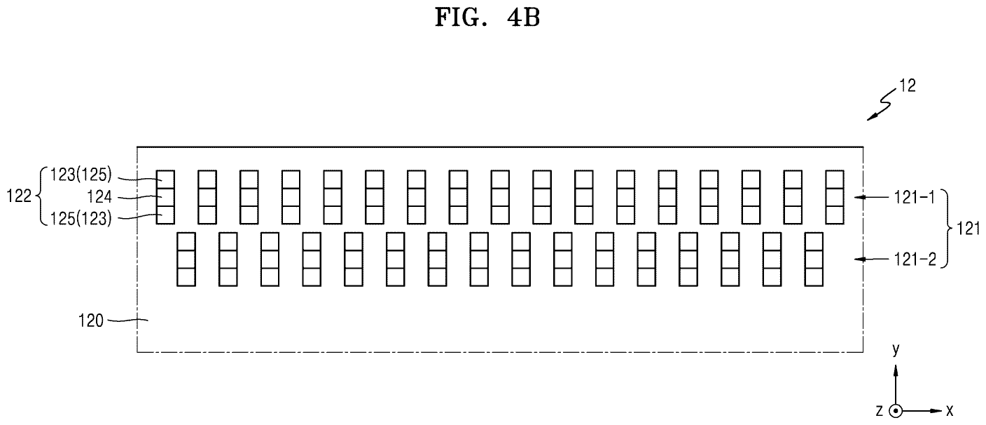

FIG. 4A is a plan view of a portion of an embodiment of the display circuit board 12.

Referring to FIG. 4A, the display circuit board 12 may include a plurality of pad units 122 arranged in one region. In an embodiment, the region where the pad units 122 are arranged may be a region where the display circuit board 12 and the substrate 100 of FIG. 1A overlap each other or a region where the display circuit board 12 and the circuit film 14 of FIG. 2A overlap each other.

The display circuit board 12 may include a display circuit board substrate 120. The display circuit board substrate 120 may be a flexible substrate or a rigid substrate. The plurality of pad units 122 may be arranged on the display circuit board substrate 120. In an embodiment, the plurality of pad units 122 may be arranged on a top surface (a +z direction surface) of the display circuit board substrate 120, for example. In an embodiment, the plurality of pad units 122 may be arranged in a row extending in one direction, e.g., an x direction. In an embodiment, the plurality of pad units 122 may include a plurality of pad rows 121 extending in the x direction as shown in FIG. 4A. In an embodiment, the plurality of pad units 122 may be arranged in a first pad row 121-1 extending in the x direction and a second pad row 121-2 arranged in a −y direction of the first pad row 121-1, for example. Obviously, the disclosure is not limited to two pad rows 121, and there may be three or more pad rows.

In an embodiment, the pad units 122 arranged in the first pad row 121-1 and the pad units 122 arranged in the second pad row 121-2 may not overlap each other. In an embodiment, the pad units 122 arranged in the first pad row 121-1 and the pad units 122 arranged in the second pad row 121-2 may be alternately arranged, for example. In other words, a virtual straight line parallel to a y direction may not simultaneously pass through the first pad row 121-1 and the second pad row 121-2.

In an embodiment, in the plurality of pad units 122, a predetermined number of pad units 122 may gather as a group, there may be a plurality of groups, and a distance between the pad units 122 may be less than a distance between the groups. In FIG. 4A, one group of pad units 122 include five pad units 122 in the first pad row 121-1 and four pad units 122 in the second pad row 121-2, but the disclosure is not necessarily limited by such numbers.

Each of the pad units 122 may include a first pad 123, a second pad 125, and an insulating layer 124 between the first pad 123 and the second pad 125. In an embodiment, the second pad 125 may be disposed in the −y direction of the first pad 123. In an embodiment, the second pad 125 may be disposed in a +y direction of the first pad 123. In an embodiment, the first pad 123, the insulating layer 124, and the second pad 125 may be sequentially arranged in the +y direction or the −y direction, and the pad unit 122 may extend in the y direction. In an embodiment, the first pad 123 and the second pad 125 may be portions that contact the pads of the substrate 100 of FIG. 1B or the pads of the circuit film 14 of FIG. 2B. In an embodiment, the insulating layer 124 may separate the first pad 123 and the second pad 125 such that the first pad 123 and the second pad 125 are not electrically connected to each other.

FIG. 4A is a plan view of a portion of an embodiment of the display circuit board 12.

Referring to FIG. 4B, the pad rows 121 may not include a group of the pad units 122. In an embodiment, the first pad row 121-1 may include the plurality of pad units 122 that are arranged at regular intervals. In an embodiment, the second pad row 121-2 may include the plurality of pad units 122 that are arranged at regular intervals. In an embodiment, the first pad row 121-1 and the second pad row 121-2 may be alternately arranged. In other words, a virtual straight line parallel to the y direction may not simultaneously pass through the pad unit 122 included in the first pad row 121-1 and the pad unit 122 included in the second pad row 121-2.

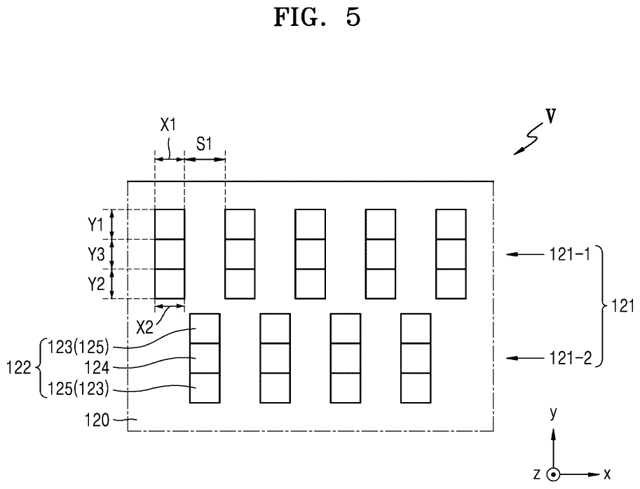

FIG. 5 is an enlarged plan view of a portion of the display circuit board 12. FIG. 5 is an enlarged plan view of a region V of FIG. 4A.

Referring to FIG. 5, the plurality of pad units 122 may be arranged on the display circuit board substrate 120 in the first pad row 121-1 and the second pad row 121-2. The pad units 122 of the first pad row 121-1 and the pad units 122 of the second pad row 121-2 may be alternately arranged.

The pad unit 122 may include the first pad 123, the insulating layer 124, and the second pad 125. In an embodiment, the first pad 123, the insulating layer 124, and the second pad 125 may be arranged in the −y direction in the stated order or the second pad 125, the insulating layer 124, and the first pad 123 may be arranged in the −y direction in the stated order. Hereinafter, for convenience of description, a case where the first pad 123, the insulating layer 124, and the second pad 125 are arranged in the −y direction in the stated order will be described.

A width (or an x direction length) of the first pad 123 may be defined as a first width X1. A length (or a y direction length) of the first pad 123 may be defined as a first length Y1. A width (or an x direction length) of the second pad 125 may be defined as a second width X2. A length (or a y direction length) of the second pad 125 may be defined as a second length Y2. A length (or a y direction length) of the insulating layer 124 may be defined as a third length Y3.

Characteristics described below may be identically applied to the pad units 122 arranged in the first pad row 121-1 and the second pad row 121-2.

In an embodiment, the first width X1 and the second width X2 may be the same. In an embodiment, the x direction length of the insulating layer 124 may be the same as the first width X1 and/or the second width X2. In an embodiment, the first length Y1 and the second length Y2 may be the same. In an embodiment, the third length Y3 may be the same as or greater than the first length Y1 and/or the second length Y2. In an embodiment, the first width X1 may be the same as the first length Y1. In an embodiment, the second width X2 may be the same as the second length Y2. In an embodiment, the x direction length of the insulating layer 124 may be the same as the third length Y3. In an embodiment, the first pad 123, the insulating layer 124, and the second pad 125 may each have an approximately square shape in which the x direction length and the y direction length are the same, and the pad unit 122 may have an approximately quadrangular shape, e.g., rectangular shape in which the y direction length is about three times greater than the x direction length.

An interval between the adjacent pad units 122 may be defined as a first interval S1. In an embodiment, the intervals between the adjacent pad units 122 may be the same. In other words, the first intervals S1 may be uniform. In an embodiment, the first interval S1 may be the same as or greater than the first width X1. In an embodiment, the first interval S1 may be the same as or greater than the second width X2. Accordingly, when viewed in the y direction, the pad units 122 arranged in the first pad row 121-1 and the pad units 122 arranged in the second pad row 121-2 may not overlap each other.

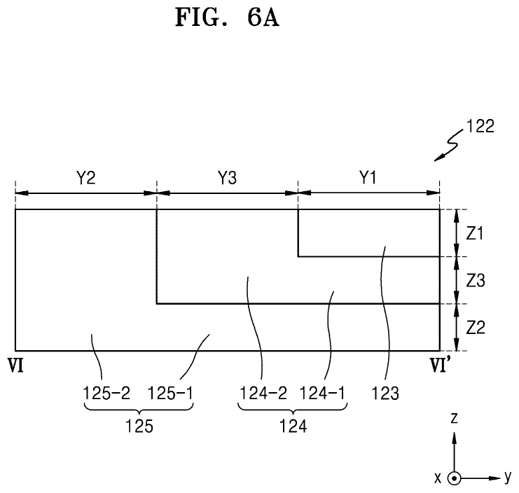

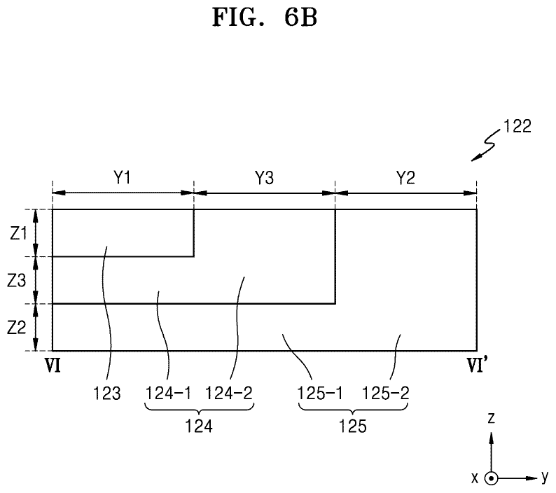

FIG. 6A is a cross-sectional view of an embodiment of the pad unit 122. FIG. 6A may be an embodiment of a cross-sectional view of the pad unit 122, taken along line VI-VI′ of FIG. 4A.

Referring to FIG. 6A, the first pad 123 and the second pad 125 may be arranged such that a top surface of the first pad 123 is disposed further in the +y direction than a top surface of the second pad 125.

The first pad 123 may be disposed on the second pad 125. The insulating layer 124 may be disposed between the first pad 123 and the second pad 125. In an embodiment, the first pad 123 may have a shape extending in the y direction.

In an embodiment, the second pad 125 may have a shape extending in a z direction and then bent to extend the y direction. In an alternative embodiment, it may be described that the second pad 125 may have a shape extending in the y direction and then bent to extend in the z direction. In an embodiment, a portion of the second pad 125 may overlap the first pad 123. In an embodiment, a first portion 125-1 of the second pad 125, which extends in the y direction, may overlap the first pad 123, for example. In an embodiment, a y direction length of the first portion 125-1 of the second pad 125 may be greater than a y direction length of the first pad 123. In other words, a portion of the first portion 125-1 of the second pad 125 may overlap the first pad 123. In an embodiment, the second pad 125 may include a second portion 125-2 that does not overlap the first pad 123. The second portion 125-2 of the second pad 125 may be a portion extending in the z direction.

In an embodiment, the insulating layer 124 may have a shape extending in the z direction and then bent to extend in the y direction. In an alternative embodiment, it may be described that the insulating layer 124 may have a shape extending in the y direction and then bent to extend in the z direction. In an embodiment, a portion of the insulating layer 124 may overlap the first pad 123. In an embodiment, a first portion 124-1 of the insulating layer 124, which extends in the y direction, may overlap the first pad 123. In an embodiment, a y direction length of the first portion 124-1 of the insulating layer 124 may be the same as the y direction length of the first pad 123, for example. In other words, the first portion 124-1 of the insulating layer 124 may cover an entirety of the first pad 123. In an embodiment, the insulating layer 124 may include a second portion 124-2 that does not overlap the first pad 123. The second portion 124-2 of the insulating layer 124 may be a portion extending in the z direction. In an embodiment, the first portion 124-1 of the insulating layer 124 may be disposed between the first pad 123 and the first portion 125-1 of the second pad 125. In an embodiment, the second portion 124-2 of the insulating layer 124 may be disposed between the first pad 123 and the second portion 125-2 of the second pad 125.

Accordingly, the insulating layer 124 may be disposed entirely in the −y direction and the −z direction, based on the first pad 123. The second pad 125 may be disposed entirely in the −y direction and the −z direction, based on the insulating layer 124.

In an embodiment, the top surface of the pad unit 122 may include the top surface of the first pad 123, the top surface of the insulating layer 124, and the top surface of the second pad 125. In an embodiment, the top surface of the pad unit 122 may include the top surface of the first pad 123, the top surface of the second portion 124-2 of the insulating layer 124, and the top surface of the second portion 125-2 of the second pad 125, for example. In an embodiment, the top surface of the pad unit 122 may be disposed on one plane. In an embodiment, the top surface of the first pad 123, the top surface of the second portion 124-2 of the insulating layer 124, and the top surface of the second portion 125-2 of the second pad 125 may be disposed on a same plane, for example.

In an embodiment, the insulating layer 124 may contact two surfaces of the first pad 123. In an embodiment, the insulating layer 124 may contact a side surface (or a −y direction surface) and/or a bottom surface (or a −z direction surface) of the first pad 123. In an embodiment, a side surface of the second portion 124-2 of the insulating layer 124, which faces the +y direction, and a side surface of the first pad 123, which faces the −y direction, may contact each other. In an embodiment, the top surface of the first portion 124-1 of the insulating layer 124, which faces the +z direction, and the bottom surface of the first pad 123, which faces the −z direction, may contact each other. Accordingly, a portion of each of the side surface and the top surface of the insulating layer 124 may be covered by the first pad 123. In an embodiment, it may be described that surfaces of the insulating layer 124, which are covered by the first pad 123, share an edge.

In an embodiment, the insulating layer 124 may contact two surfaces of the second pad 125. In an embodiment, the insulating layer 124 may contact a side surface (or a +y direction surface) and/or a top surface (or a +z direction surface) of the second pad 125. In an embodiment, a side surface of the second portion 124-2 of the insulating layer 124, which faces the −y direction, and the side surface of the second portion 125-2 of the second pad 125, which faces the +y direction, may contact each other. In an embodiment, a bottom surface of the insulating layer 124, which faces the −z direction, and a top surface of the second portion 125-2 of the second pad 125, which faces the +z direction, may contact each other. Accordingly, a portion of each of the side surface and the top surface of the second pad 125 may be covered by the insulating layer 124. In an embodiment, it may be described that surfaces of the second pad 125, which are covered by the insulating layer 124, share an edge. According to the above-described structure, the first pad 123 and the second pad 125 may be insulated from each other.

In the above, the y direction lengths of the first pad 123, the second pad 125, and the insulating layer 124 have been defined as the first length Y1, the second length Y2, and the third length Y3, respectively. Here, the third length Y3 of the insulating layer 124 may be substantially a y direction length of the second portion 124-2 of the insulating layer 124. Also, the second length Y2 of the second pad 125 may be substantially a y direction length of the second portion 125-2 of the second pad 125.

In an embodiment, a y direction length of the first portion 124-1 of the insulating layer 124 may be the same as the first length Y1. Accordingly, an entirety of the length of the insulating layer 124 may be the same as the sum of the first length Y1 and the third length Y3. In an embodiment, the y direction length of the first portion 125-1 of the second pad 125 may be the same as the sum of the first length Y1 and the third length Y3. Accordingly, an entirety of the length of the second pad 125 may be the same as the sum of the first length Y1, the second length Y2, and the third length Y3.

A thickness (or a z direction length) of the first pad 123 may be defined as a first thickness Z1. A thickness (or a z direction length) of the first portion 125-1 of the second pad 125 may be defined as a second thickness Z2. A thickness (or a z direction length) of the first portion 125-1 of the insulating layer 124 may be defined as a third thickness Z3.

In an embodiment, a thickness of the second portion 124-2 of the insulating layer 124 may be the same as the sum of the first thickness Z1 and the third thickness Z3. Accordingly, thicknesses of the first portion 124-1 and the second portion 124-2 of the insulating layer 124 may be different from each other. In an embodiment, the thickness of the first portion 124-1 of the insulating layer 124 may be less than the thickness of the second portion 124-2, for example. In an embodiment, the thickness of the second portion 125-2 of the second pad 125 may be the same as the sum of the first thickness Z1, the second thickness Z2, and the third thickness Z3. Accordingly, the thicknesses of the first portion 125-1 and the second portion 125-2 of the second pad 125 may be different from each other. In an embodiment, the thickness of the first portion 125-1 of the second pad 125 may be less than the thickness of the second portion 125-2, for example.

In an embodiment, the first thickness Z1 and the third thickness Z3 may be the same. In an embodiment, the second thickness Z2 may be the same as or greater than the first thickness Z1 and/or the third thickness Z3. In an embodiment, the second thickness Z2 may be the same as the sum of the first thickness Z1 and the third thickness Z3.

FIG. 6B is a cross-sectional view of an embodiment of the pad unit 122. FIG. 6B may be another embodiment of a cross-sectional view of the pad unit 122, taken along line VI-VI′ of FIG. 4A.

Referring to FIG. 6B, the first pad 123 and the second pad 125 may be arranged such that the top surface of the first pad 123 is disposed further in the −y direction than the top surface of the second pad 125.

The insulating layer 124 may be disposed entirely in the +y direction and the −z direction, based on the first pad 123. The second pad 125 may be disposed entirely in the +y direction and the −z direction, based on the insulating layer 124.

The embodiment shown in FIG. 6B may be different from the embodiment shown in FIG. 6A with respect to surfaces of the first pad 123, which are covered by the insulating layer 124, and surfaces of the insulating layer 124, which are covered by the second pad 125.

In an embodiment, the insulating layer 124 may contact a side surface (or a +y direction surface) and/or the bottom surface (or the −z direction surface) of the first pad 123. In an embodiment, a side surface of the second portion 124-2 of the insulating layer 124, which faces the −y direction, and a side surface of the first pad 123, which faces the +y direction, may contact each other. Accordingly, the side surface of the first pad 123, which faces the +y direction, and the bottom surface of the first pad 123, which faces the −z direction, may be covered by the insulating layer 124.

In an embodiment, the insulating layer 124 may contact a side surface (or a −y direction surface) and/or the top surface (or the +z direction surface) of the second pad 125. In an embodiment, a side surface of the second portion 124-2 of the insulating layer 124, which faces the +y direction, and a side surface of the second portion 125-2 of the second pad 125, which faces the −y direction, may contact each other. Accordingly, the side surface of the insulating layer 124, which faces the +y direction, and the bottom surface of the insulating layer 124, which faces the −z direction, may be covered by the second pad 125.

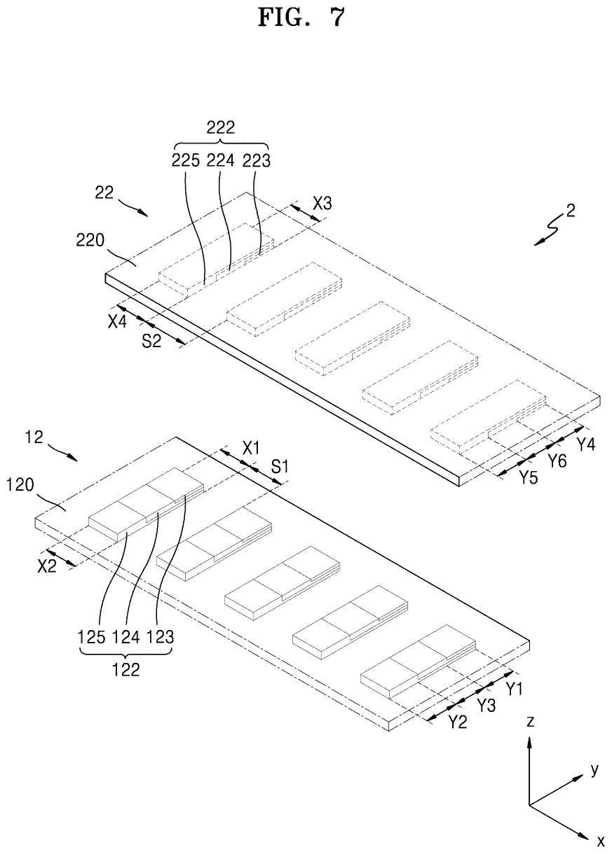

FIG. 7 is a perspective view of an embodiment of a portion of a circuit board test apparatus 2.

Referring to FIG. 7, the circuit board test apparatus 2 may include a test circuit board 22. The display circuit board 12 to be tested may be disposed (e.g., mounted) on the circuit board test apparatus 2.

The test circuit board 22 may be configured in a similar manner as the display circuit board 12. In an embodiment, the test circuit board 22 may include a test circuit board substrate 220 and a plurality of test pad units 222 arranged on the test circuit board substrate 220. The test circuit board substrate 220 may correspond to the display circuit board substrate 120 of the display circuit board 12 and the test pad unit 222 may correspond to the pad unit 122 of the display circuit board 12.

The display circuit board 12 and the test circuit board 22 may be arranged such that top surfaces thereof face each other. The top surface of the display circuit board 12 may be a surface where the pad unit 122 is disposed on the display circuit board substrate 120, i.e., a +z direction surface. The top surface of the test circuit board 22 may be a surface where the test pad unit 222 is disposed on the test circuit board substrate 220, i.e., a −z direction surface. Hereinafter, the top surface of the display circuit board 12 may denote a surface where the pad unit 122 is disposed and the top surface of the test circuit board 22 may denote a surface where the test pad unit 222 is disposed.

The test pad unit 222 may be configured in a similar manner to the pad unit 122. In an embodiment, the test pad unit 222 may include a first test pad 223, a test insulating layer 224, and a second test pad 225. In an embodiment, the first test pad 223, the test insulating layer 224, and the second test pad 225 may have characteristics of the first pad 123, the insulating layer 124, and the second pad 125 described above, respectively. In an embodiment, the test pad unit 222 may be obtained by arranging a same element as the pad unit 122 on the test circuit board substrate 220.

In an embodiment, the first test pad 223 may have a third width X3. The third width X3 may have features of the first width X1. In an embodiment, the second test pad 225 may have a fourth width X4. The fourth width X4 may have features of the second width X2. In an embodiment, an interval between the adjacent test pad unit 222 may be defined as a second interval S2. The second interval S2 may have features of the first interval S1. In an embodiment, the first test pad 223 may have a fourth length Y4. The fourth length Y4 may have features of the first length Y1. In an embodiment, the second test pad 225 may have a fifth length Y5. The fifth length Y5 may have features of the second length Y2. In an embodiment, the test insulating layer 224 may have a sixth length Y6. The sixth length Y6 may have features of the third length Y3. Although not illustrated in FIG. 7, features of thicknesses of components of the test pad unit 222, e.g., the first test pad 223, the test insulating layer 224, and the second test pad 225, may be the same as or similar to features of thicknesses of components of the pad unit 122 described above.

In an embodiment, the test circuit board 22 may translate with respect to the display circuit board 12. Accordingly, the test pad unit 222 may translate with respect to the pad unit 122.

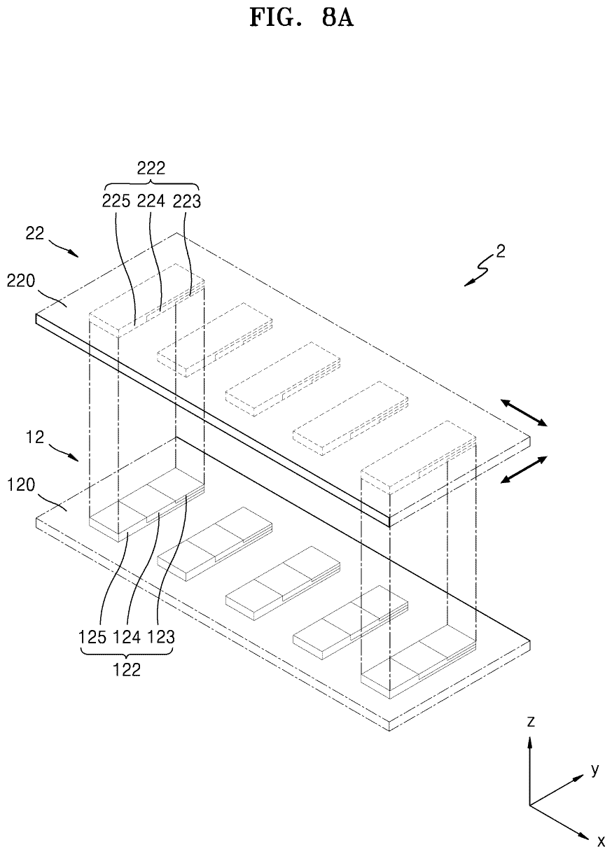

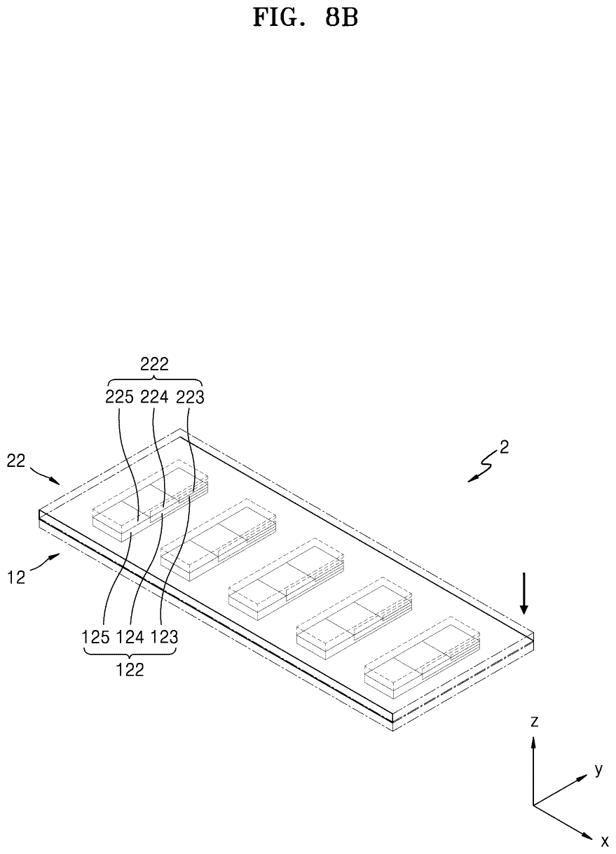

FIGS. 8A and 8B are perspective views illustrating an embodiment of stages of a test method for the display circuit board 12.

Referring to FIG. 8A, the display circuit board 12 and the test circuit board 22 may be aligned with each other. In an embodiment, the test circuit board 22 may translate with respect to the display circuit board 12. In an embodiment, the test circuit board 22 may move in the x direction and/or the y direction and/or the z direction with respect to the display circuit board 12, for example. In an embodiment, the display circuit board 12 may be fixed and the test circuit board 22 may be moved. In an embodiment, the test circuit board 22 may be fixed and the display circuit board 12 may be moved.

The alignment of the display circuit board 12 and the test circuit board 22 may be performed by aligning the pad unit 122 and the test pad unit 222. In an embodiment, when the pad unit 122 and the test pad unit 222 are completely aligned, the pad unit 122 and the test pad unit 222 may completely overlap each other when viewed in the +z direction. Here, the first test pad 223 may overlap the first pad 123 and may not overlap the insulating layer 124 and/or the second pad 125. Also, the second test pad 225 may overlap the second pad 125 and may not overlap the insulating layer 124 and/or the first pad 123. Also, the test pad unit 222 may not overlap another pad unit 122 adjacent to the overlapping pad unit 122. In other words, the test pad unit 222 may overlap only one corresponding pad unit 122. In an embodiment, so as to align the pad unit 122 and the test pad unit 222, the test circuit board 22 may be moved in the x direction and/or the y direction with respect to the display circuit board 12.

Referring to FIG. 8B, while the display circuit board 12 and the test circuit board 22 are aligned, the display circuit board 12 and the test circuit board 22 may approach towards each other. In other words, the test circuit board 22 may be brought close to the display circuit board 12.

In an embodiment, as shown in FIG. 8B, the test circuit board 22 may be descended to be close to the display circuit board 12. In an embodiment, unlike as shown in FIG. 8B, the display circuit board 12 may be ascended to be close to the test circuit board 22.

In an embodiment, the display circuit board 12 and the test circuit board 22 may be brought close to each other so as to bring the pad unit 122 and the test pad unit 222 close to each other. In an embodiment, the top surface (or the +z direction surface) of the pad unit 122 and the top surface (or the −z direction surface) of the test pad unit 222 may contact each other. In an embodiment, the first test pad 223 may contact the first pad 123 and may not contact the insulating layer 124 and/or the second pad 125. In an embodiment, the second test pad 225 may contact the second pad 125 and may not contact the insulating layer 124 and/or the first pad 123. In an embodiment, the test pad unit 222 may contact only one pad unit 122.

The pad unit 122 and the test pad unit 222 may be electrically connected to each other, and in addition, the display circuit board 12 and the test circuit board 22 may be electrically connected to each other. Then, a voltage may be applied to the test circuit board 22 so as to transmit an electric signal to the display circuit board 12 through the test pad unit 222 and the pad unit 122. It may be tested whether a printed circuit of the display circuit board 12 has been manufactured as intended, based on whether a desired response signal is obtained by transmitting the electric signal through the display circuit board 12. When corresponding response signals for various electric signals transmitted to the display circuit board 12 through the test circuit board 22 are the same as those desired, the display circuit board 12 may be determined to be normal and transferred for a next process. When the corresponding response signals for the various electric signals transmitted to the display circuit board 12 through the test circuit board 22 are different from those desired, the printed circuit of the display circuit board 12 may be determined to be defective and the display circuit board 12 may be discarded or transferred for a reassembly process.

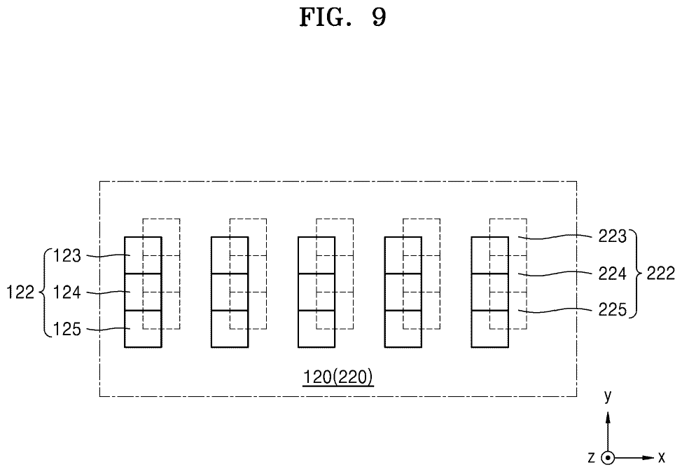

During such a test process, a degree of alignment of the pad unit 122 and the test pad unit 222 may be an important factor in testing the display circuit board 12. In FIGS. 8A and 8B, the pad unit 122 and the test pad unit 222 are completely aligned to completely overlap each other, but this may not be the case in an actual process. In an embodiment, an alignment error in which the pad unit 122 and the test pad unit 222 only partially overlap each other may occur, for example. When the test pad unit 222 contacts the plurality of pad units 122 simultaneously due to the alignment error, a short may occur between the adjacent pad units 122. In an alternative embodiment, when the first test pad 223 contacts the first pad 123 and the second pad 125 simultaneously, a short may occur between the first pad 123 and the second pad 125. In an alternative embodiment, even when the second test pad 225 contacts the first pad 123 and the second pad 125 simultaneously, a short may occur between the first pad 123 and the second pad 125. In this case, the display circuit board 12 may be determined to be unable to be tested or determined as defective despite that it is normal. Such possibilities may be reduced by features of the embodiments, as will be described below with reference to FIGS. 9 to 11.

FIG. 9 is a plan view of an embodiment of an alignment state of the pad unit 122 and the test pad unit 222.

Referring to FIG. 9, the pad unit 122 and the test pad unit 222 may partially overlap each other. In other words, a portion of the test pad unit 222 may overlap the pad unit 122 and another portion thereof may overlap a space between the adjacent pad units 122.

The first test pad 223 may overlap the first pad 123 and may not overlap the insulating layer 124 and the second pad 125. The test insulating layer 224 may overlap the first pad 123 and the insulating layer 124 and may not overlap the second pad 125. The second test pad 225 may overlap the insulating layer 124 and the second pad 125 and may not overlap the first pad 123. When the test pad unit 222 contacts the pad unit 122 while in the state as shown in FIG. 9, the first test pad 223 may be electrically connected only to the first pad 123 and the second test pad 225 may be electrically connected only to the second pad 125. In this case, a short does not occur and a test process may be normally performed.

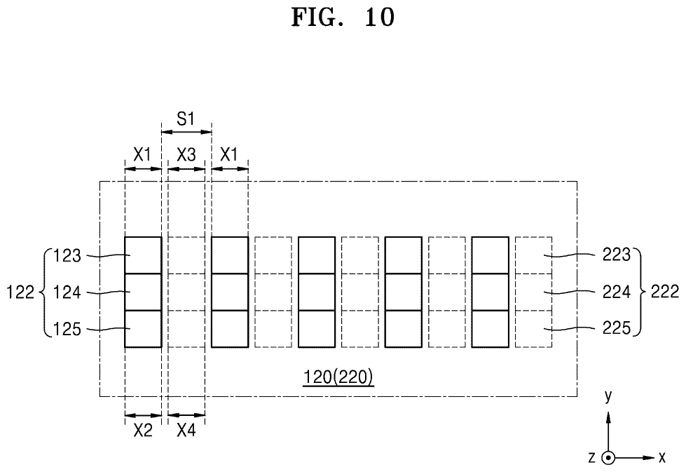

FIG. 10 is a plan view of an embodiment of an alignment state of the pad unit 122 and the test pad unit 222.

Referring to FIG. 10, misalignment, e.g., x direction misalignment, may occur between the test pad unit 222 and the pad unit 122. In an embodiment, the test pad unit 222 may not overlap the pad unit 122. In an embodiment, the test pad unit 222 may be disposed in a space between the adjacent pad units 122, for example. Accordingly, in a plane, the test pad unit 222 and the pad unit 122 may be alternately arranged in the x direction.

Here, the first interval S1 that is the interval between the adjacent pad units 122 may be the same as or greater than the third width X3 and/or the fourth width X4, which is the width of the test pad unit 222. In an embodiment, the first interval S1 may be greater than the third width X3 that is the width of the first test pad 223. In an embodiment, the first interval S1 may be greater than the fourth width X4 that is the width of the second test pad 225. Accordingly, even when the test pad unit 222 is aligned to be completely spaced apart from one pad unit 122, the test pad unit 222 may not overlap another pad unit 122. In other words, one pad unit 122 may not simultaneously overlap the plurality of pad units 122. Accordingly, a short may be prevented from occurring between the adjacent pad units 122 as one test pad unit 222 contacts the plurality of pad units 122 simultaneously.

When the test pad unit 222 and the pad unit 122 are aligned as shown in FIG. 10, the test pad unit 222 and the pad unit 122 may not contact each other even when they are brought close to each other. Accordingly, an electric signal applied to the test pad unit 222 is not transmitted to the pad unit 122, and thus, it may be identified that alignment is abnormal and the test pad unit 222 and the pad unit 122 may be realigned. As a result, owing to a margin (e.g., the first interval S1) secured between the adjacent pad units 122, even when misalignment (e.g., misalignment in the x direction) occurs between the test pad unit 222 and the pad unit 122 in one direction, a situation where a display circuit board is determined to be defective due to a short between the pad units 122 may be prevented.

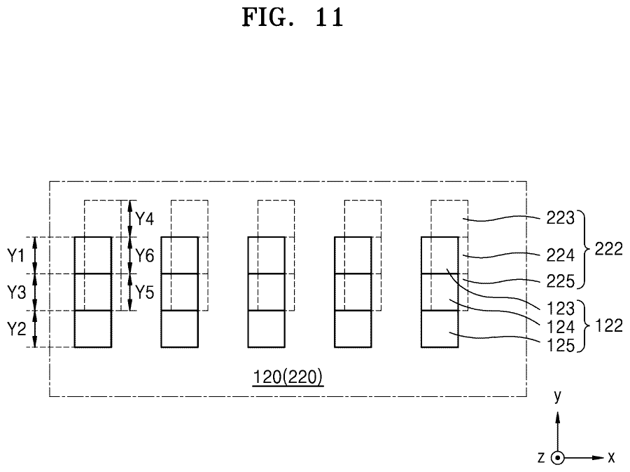

FIG. 11 is a plan view of an embodiment of an alignment state of the pad unit 122 and the test pad unit 222.

Referring to FIG. 11, misalignment, e.g., y direction misalignment, may occur between the test pad unit 222 and the pad unit 122. In an embodiment, the test pad unit 222 may partially overlap the pad unit 122.

In an embodiment, the test pad unit 222 may be disposed further in the +y direction than the pad unit 122, the test insulating layer 224 may overlap the first pad 123, and the second test pad 225 may overlap the insulating layer 124. In an embodiment, the test pad unit 222 may be disposed further in the −y direction than the pad unit 122, the first test pad 223 may overlap the insulating layer 124, and the test insulating layer 224 may overlap the second pad 125.

In an embodiment, the third length Y3 of the insulating layer 124 may be the same as or greater than the first length Y1 of the first pad 123 and the second length Y2 of the second pad 125. In an embodiment, the sixth length Y6 of the test insulating layer 224 may be the same as or greater than the fourth length Y4 of the first test pad 223 and the fifth length Y5 of the second test pad 225. In an embodiment, the third length Y3 and the sixth length Y6 may be the same as each other and may be greater than the first length Y1, the second length Y2, the fourth length Y4, and the fifth length Y5. In FIG. 11, the first to sixth lengths Y1 to Y6 are the same.

Accordingly, even when misalignment between the test pad unit 222 and the pad unit 122 occurs in the y direction, the first test pad 223 and the second test pad 225 may not simultaneously overlap the first pad 123 and the second pad 125. In an embodiment, as shown in FIG. 11, the second test pad 225 may overlap the insulating layer 124. The third length Y3 of the insulating layer 124 may be the same as or greater than the fifth length Y5 of the second test pad 225, for example. In the embodiment shown in FIG. 11, when the test pad unit 222 is moved in the +y direction, the second test pad 225 may overlap the first pad 123 but does not overlap the second pad 125. In the embodiment shown in FIG. 11, when the test pad unit 222 is moved in the −y direction, the second test pad 225 may overlap the second pad 125 but does not overlap the first pad 123. Accordingly, the second test pad 225 does not overlap the first pad 123 and the second pad 125 simultaneously. Accordingly, the second test pad 225 is unable to contact the first pad 123 and the second pad 125 simultaneously, a short between the first pad 123 and the second pad 125 may be prevented.

When the test pad unit 222 and the pad unit 122 are aligned as shown in FIG. 11, the first and second pads 123 and 125 and the first and second test pads 223 and 225 may not contact each other even when the test pad unit 222 and the pad unit 122 are brought close to each other. Accordingly, an electric signal applied to the test pad unit 222 is not transmitted to the pad unit 122, and thus, it may be identified that alignment is abnormal and the test pad unit 222 and the pad unit 122 may be realigned. As a result, owing to a margin secured through the insulating layer 124 between the first pad 123 and the second pad 125, even when misalignment (e.g., misalignment in the y direction) occurs between the test pad unit 222 and the pad unit 122 in one direction, a situation where a display circuit board is determined to be defective due to a short between the first and second pads 123 and 125 may be prevented. Obviously, in the embodiment shown in FIG. 11, when the test pad unit 222 is moved in the +y direction such that the second test pad 225 overlaps and contacts the first pad 123 and the insulating layer 124, it may be identified that there is an error in alignment. When the test pad unit 222 is moved in the −y direction such that the second test pad 225 overlaps and contacts the insulating layer 124 and the second pad 125 in the embodiment shown in FIG. 11, the embodiment shown in FIG. 9 may be realized and a test process may be normally performed.

According to the above-described embodiments, provided are a display apparatus including a display circuit board having a contact margin equal to or greater than a size of pads, and a test circuit board corresponding to the display circuit board.

The effects of the disclosure are not limited to those mentioned above, and other effects that are not mentioned may be clearly understood by one of ordinary skill in the art from the scope of claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a substrate including a display area where a plurality of display elements is disposed; and
a display circuit board disposed outside the display area, the display circuit board comprising:
a first pad and a second pad, which are disposed on the display circuit board and connected to the substrate; and
an insulating layer disposed between the first pad and the second pad,
wherein the first pad overlaps the second pad and a thickness of at least a portion of the second pad is different from a thickness of the first pad.

2. The display apparatus of claim 1, wherein the second pad comprises a first portion overlapping the first pad and a second portion non-overlapping the first pad, wherein a thickness of the first portion is less than a thickness of the second portion.

3. The display apparatus of claim 2, wherein the insulating layer comprises a first portion disposed between the first pad and the first portion of the second pad and a second portion disposed between the first pad and the second portion of the second pad.

4. The display apparatus of claim 3, wherein a thickness of the first portion of the insulating layer is greater than or equal to at least one of the thickness of the first pad and the thickness of the first portion of the second pad.

5. The display apparatus of claim 1, wherein top surfaces of the first pad, the second pad, and the insulating layer, respectively, are disposed in a same plane.

6. The display apparatus of claim 1, wherein the insulating layer contacts at least one of the first pad and the second pad on two surfaces of the at least one of the first pad and the second pad, and
the two surfaces extend along different directions from each other.

7. The display apparatus of claim 6, wherein the insulating layer contacts a side surface and a bottom surface of the first pad, which face the second pad, and contacts a side surface and a top surface of the second pad, which face the first pad.

8. The display apparatus of claim 6, wherein the two surfaces extending in the different directions from each other share a same edge.

9. The display apparatus of claim 1, further comprising a plurality of first pads spaced apart from each other in a first direction and a plurality of second pads spaced apart from each other in the first direction,
wherein, in a plan view, a distance between adjacent first pads of the plurality of first pads in the first direction is greater than or equal to a width of one of the plurality of first pads in the first direction.

10. The display apparatus of claim 1, wherein, in a plan view, the first pad and the second pad are spaced apart from each other in a second direction with the insulating layer therebetween, and
a length of the insulating layer in the second direction is greater than or equal to than a length of at least one of the first pad and the second pad in the second direction.

11. A test circuit board for testing a display circuit board disposed outside a display apparatus, the test circuit board comprising:
a first test pad;
a second test pad spaced apart from the first test pad; and
an insulating layer disposed between the first test pad and the second test pad,
wherein the first test pad overlaps the second test pad and a thickness of at least a portion of the second test pad is different from a thickness of the first test pad.

12. The test circuit board of claim 11, wherein the second test pad comprises a first portion overlapping the first test pad and a second portion non-overlapping the first test pad, wherein a thickness of the first portion is less than a thickness of the second portion.

13. The test circuit board of claim 12, wherein the insulating layer comprises a first portion disposed between the first test pad and the first portion of the second test pad and a second portion disposed between the first test pad and the second portion of the second test pad.

14. The test circuit board of claim 13, wherein a thickness of the first portion of the insulating layer is greater than or equal to at least one of the thickness of the first test pad and the thickness of the first portion of the second test pad.

15. The test circuit board of claim 11, wherein top surfaces of the first test pad, the second test pad, and the insulating layer are disposed in a same plane.

16. The test circuit board of claim 11, wherein the insulating layer contacts at least one of the first test pad and the second test pad on two surfaces of the at least one of the first test pad and the second test pad, and
the two surfaces extend along different directions from each other.

17. The test circuit board of claim 16, wherein the insulating layer contacts a side surface and a bottom surface of the first test pad, which face the second test pad, and contacts a side surface and a top surface of the second test pad, which face the first test pad.

18. The test circuit board of claim 16, wherein the two surfaces extending in the different directions from each other share a same edge.

19. The test circuit board of claim 11, further comprising a plurality of first test pads spaced apart from each other in a first direction and a plurality of second test pads spaced apart from each other in the first direction,
wherein, in a plan view, a distance between adjacent first test pads of the plurality of first test pads in the first direction is greater than or equal to a length of one of the plurality of first test pads in the first direction.

20. The test circuit board of claim 11, wherein, in a plan view, the first test pad and the second test pad are spaced apart from each other in a second direction with the insulating layer therebetween, and
a length of the insulating layer in the second direction is greater than or equal to a length of at least one of the first test pad and the second test pad in the second direction.
